(19) United States
(12) Patent Application Publication
(10) Pub. No.: US 2013/0207245 A1
(43) Pub. Date: Aug. 15, 2013

(54) METHODS FOR MAKING POROUS INSULATING FILMS AND SEMICONDUCTOR DEVICES INCLUDING THE SAME

(71) Applicant: Renesas Electronics Corporation, (US)

(72) Inventors: Naoya INOUE, Kanagawa (JP); Masayoshi TAGAMI, Kanagawa (JP)

(73) Assignee: Renesas Electronics Corporation, Kanagawa (JP)

(21) Appl. No.: 13/765,183

(22) Filed: Feb. 12, 2013

Related U.S. Application Data
(60) Provisional application No. 61/599,212, filed on Feb. 15, 2012.

(51) Int. Cl. H01L 21/768; H01L 23/532

(52) U.S. Cl. CPC H01L 21/76825; H01L 23/5329
USPC 257/632; 438/778

(57) ABSTRACT

Low-k porous insulating films with a high modulus of elasticity are made by depositing alkylated cyclic siloxane precursors over a semiconductor substrate by CVD. Plasma enhancement of the CVD is performed either during CVD or in situ on the deposited film. A UV cure of the film is effected under controlled temperature and time conditions, which generates a tight bonding structure between adjacent ring moieties without disrupting the Si—O ring bonding.

### BACKGROUND

The invention relates to methods for making porous insulating films and semiconductor devices including the same.

As semiconductor devices have continued to decrease in size, it has become necessary to take more effective measures to prevent capacitive crosstalk between copper interconnect lines. As capacitive crosstalk is dependent upon not only the distance between conductors but also the dielectric constant (k) of the material of the interconnect layer in which the conductors are formed, efforts have been made to develop new low-k dielectric materials for use in such interconnect layers.

“Low-k” refers to materials whose dielectric constant is less than that of silicon dioxide, that is, less than about 3.9. Low-k dielectric materials include those made of materials that have an intrinsically low dielectric constant, as well as materials that are formed so as to have microporosity. In the latter case, the voids within the material serve to lower its effective k value, given that the dielectric constant of air is approximately 1.

Porosity can be introduced into low-k dielectrics by the use of porogens, which must be removed from the low-k layer in order to produce the voids. An example of such a process is described in U.S. Pat. No. 7,629,272.

The present inventors have discovered, however, that removal of the porogens leaves not only voids but also pathways opening on the surface of the low-k layer, which pathways render the low-k layer susceptible to plasma-induced damage (PID) during subsequent processing. This PID serves to increase the effective k-value of the layer.

Porosity can also be introduced by use of porogen-free materials, such as those described in U.S. Pat. No. 7,968,471. However, such low-k layers have insufficient mechanical strength. A limitation of porous low-k layers generally is that the porosity decreases the mechanical strength of the layer, as expressed most commonly in terms of its modulus of elasticity. A sufficiently high modulus of elasticity for the low-k layer is important from the standpoint of maintaining mechanical reliability, especially during the packaging process of the semiconductor products. Insufficient mechanical strength of the low-k layer can thus lead to failure of the overall semiconductor device in which the low-k layer is incorporated.

The low-k film of U.S. Pat. No. 7,968,471 is formed by plasma CVD of alkylated cyclic siloxanes including an unsaturated side chain. As the ring structure of the cyclic siloxanes forms the pores in the low-k film, it is desired to activate the side chains to effect polymerization without breaking the rings. However, an energy supply in the plasma that is low enough to avoid breaking the Si—O bonds within the ring structures, sometimes cannot provide enough energy to form tight bonding structures, whereby the modulus of the resulting film is reduced.

### SUMMARY

The present inventors have discovered that improved low-k insulating films can be formed by depositing cyclic siloxane precursor compounds over a semiconductor substrate, and then forming a porous insulating film by exposing the precursor layer to UV energy under controlled conditions.

Thus, the present invention in one aspect relates to a method of making a porous insulating film, comprising forming a precursor layer over a semiconductor substrate by depositing at least one cyclic siloxane compound having at least one hydrocarbon side chain by CVD; and converting the precursor layer to a porous insulating film by exposing the insulating film to UV energy under conditions such that adjacent molecules of the at least one cyclic siloxane compound are bonded via a hydrocarbon group and the porous insulating film has an elastic modulus as measured by a nanoindenter of greater than 5 GPa.

In preferred embodiments of the method according to the present invention, the precursor layer is formed by plasma-enhanced CVD.

In preferred embodiments of the method according to the present invention, the at least one cyclic siloxane compound is introduced into a plasma during the forming step.

In preferred embodiments of the method according to the present invention, the at least one cyclic siloxane compound is treated with plasma in situ after formation of the precursor layer.

In preferred embodiments of the method according to the present invention, the porous insulating film has a lower carbon content than the precursor layer.

In preferred embodiments of the method according to the present invention, silicon atoms of adjacent siloxane rings within the porous insulating film are joined by a methylene (—CH₂—) linkage.

In preferred embodiments of the method according to the present invention, the precursor layer is formed by plasma-enhanced CVD at a temperature within the range of 250-400° C.

In preferred embodiments of the method according to the present invention, the precursor layer is formed by plasma-enhanced CVD at an RF power in the range of 150-400 W.

In preferred embodiments of the method according to the present invention, the precursor layer is exposed to UV energy at a temperature of 250-400° C. for a time period less than 300 seconds.

In preferred embodiments of the method according to the present invention, the time period is from 75-250 seconds.

In preferred embodiments of the method according to the present invention, the time period is from 100-200 seconds.

In preferred embodiments of the method according to the present invention, the time period is from 15-150 seconds.

In preferred embodiments of the method according to the present invention, the time period is from 15-75 seconds.

In preferred embodiments of the method according to the present invention, the precursor layer is exposed to UV energy at a temperature of 300-350° C.

In preferred embodiments of the method according to the present invention, the UV energy is supplied by a broadband UV light source including a wavelength of at least 200±50 nm.

In preferred embodiments of the method according to the present invention, the precursor layer is porogen-free.

In preferred embodiments of the method according to the present invention, the at least one cyclic siloxane compound is selected from the group consisting of compounds of the formulae:

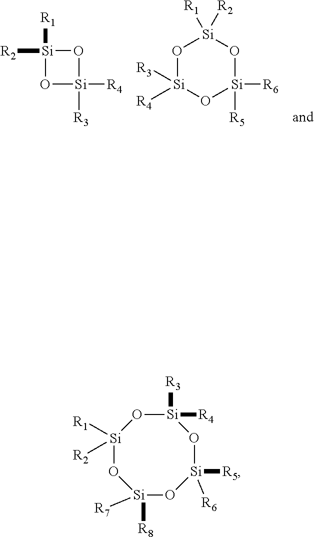

wherein R₁-R₈ are each independently selected from the group consisting of saturated C₁-C₄ alkyl and unsaturated C₂-C₄ alkylene, and wherein each of the at least one cyclic siloxane compounds comprises at least one saturated C₁-C₄ alkyl group and at least one unsaturated C₂-C₄ alkylene group.

In preferred embodiments of the method according to the present invention, the at least one cyclic siloxane compound is selected from the group consisting of compounds of the formulae:

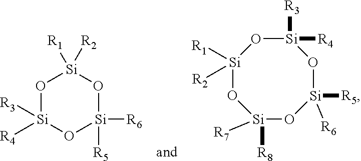

wherein R₁, R₃, R₅ and R₇ are each saturated C₁-C₄ alkyl and wherein R₂, R₄, R₆ and R₈ are each unsaturated C₂-C₄ alkylene.

In preferred embodiments of the method according to the present invention, R₁, R₃, R₅ and R₇ are each methyl, ethyl or isopropyl and wherein R₂, R₄, R₆ and R₈ are each vinyl.

In preferred embodiments of the method according to the present invention, the at least one cyclic siloxane compound comprises a mixture of compounds of the formulae:

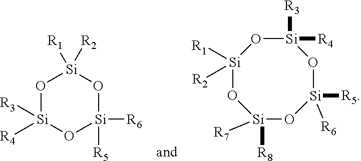

In preferred embodiments of the method according to the present invention, the mixture comprises compounds of the formula

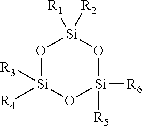

in a molar ratio of about 4:3 to compounds of the formula

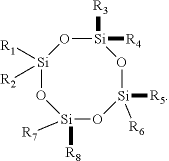

In another aspect, the present invention relates to a semiconductor device comprising a semiconductor substrate and a porous insulating film overlying the semiconductor substrate, wherein the porous insulating film is a low-k SiOCH film having cyclic siloxane moieties interconnected by hydrocarbon linkages, the porous insulating film having a carbon content of greater than 30 atomic % as measured by X-ray photoelectron spectroscopy, a porosity of less than 20% as measured by ellipsometric porosimetry, a pore size distribution wherein greater than 80% of pores have a diameter of less than 1 nm, an elastic modulus as measured by a nanoindenter of greater than 5 GPa, the porous insulating film further comprising linkages including —Si—O—, —Si—CH₂—Si—, and —Si—CₓH₂ₓ₊₁. wherein x is an integer from 1 to 4.

In preferred embodiments of the semiconductor device according to the present invention, the porous insulating film is an interlayer insulating film comprising damascene copper interconnects formed in trenches and vias in the interlayer insulating film.

In preferred embodiments of the semiconductor device according to the present invention, the carbon content is in the range of 40-60 atomic %.

In preferred embodiments of the semiconductor device according to the present invention, the porosity is in the range of 5-15%.

In preferred embodiments of the semiconductor device according to the present invention, the porous insulating film has a relative permittivity of less than 2.7.

In preferred embodiments of the semiconductor device according to the present invention, the porous insulating film has a relative permittivity of less than 2.6.

In preferred embodiments of the semiconductor device according to the present invention, the porous insulating film has an elastic modulus as measured by a nanoindenter of greater than 6 GPa.

In preferred embodiments of the semiconductor device according to the present invention, the porous insulating film has an elastic modulus as measured by a nanoindenter of greater than 7 GPa.

In preferred embodiments of the semiconductor device according to the present invention, the porous insulating film is deposited from the single precursor without porogen.

In preferred embodiments of the semiconductor device according to the present invention, the porous insulating film is formed by polymerizing molecules comprising at least one cyclic siloxane compound selected from the group consisting of compounds of the formulae:

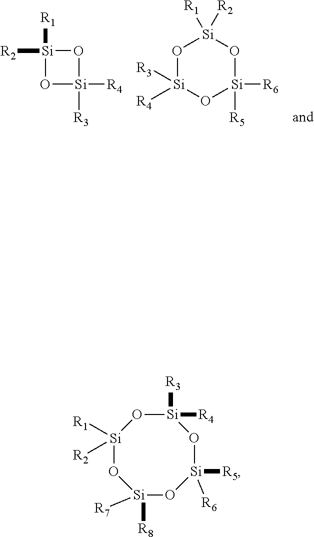

wherein R₁-R₈ are each independently selected from the group consisting of saturated C₁-C₄ alkyl and unsaturated C₂-C₄ alkylene, and wherein each of the at least one cyclic siloxane compounds comprises at least one saturated C₁-C₄ alkyl group and at least one unsaturated C₂-C₄ alkylene group.

In preferred embodiments of the semiconductor device according to the present invention, the porous insulating film is formed by polymerizing molecules comprising at least one cyclic siloxane compound selected from the group consisting of compounds of the formulae:

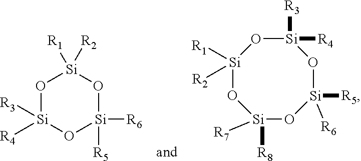

wherein R₁, R₃, R₅ and R₇ are each saturated C₁-C₄ alkyl and wherein R₂, R₄, R₆ and R₈ are each unsaturated C₂-C₄ alkylene.

In preferred embodiments of the semiconductor device according to the present invention, R₁, R₃, R₅ and R₇ are each methyl, ethyl or isopropyl and wherein R₂, R₄, R₆ and R₈ are each vinyl.

### BRIEF DESCRIPTION OF THE DRAWINGS

The invention will be more fully understood from the following detailed description of various non-limiting examples thereof, taken with reference to the accompanying drawings, in which:

FIG. 1a shows the relationship between k-value and UV cure time for an embodiment of a porous insulating film according to the present invention;

FIG. 1b shows the relationship between elastic modulus and UV cure time for an embodiment of a porous insulating film according to the present invention;

FIG. 2 shows the relationship between TDDB (Time dependent dielectric breakdown) lifetime and pore size for various porous insulating films;

FIG. 3 shows part of a semiconductor device according to an embodiment of the present invention;

FIG. 4 shows a pore size distribution for an embodiment of the present invention before and after UV cure;

FIG. 5 shows a relationship between PID and porosity/carbon ratio for various low-k porous films;

FIG. 6 shows the variation in carbon content in a film and carbon reduction with respect to a film before UV cure according to an embodiment of the invention as a function of UV cure time;

FIG. 7 shows the variation in porosity and pore size in a film according to an embodiment of the invention as a function of UV cure time;

FIG. 8 shows an FTIR analysis of a film according to an embodiment of the invention; and

FIG. 9 shows a further FTIR analysis of a film according to an embodiment of the invention.

### DETAILED DESCRIPTION

As discussed above, it is desired to enhance the film modulus for the insulator film with low dielectric constant (low-k), which has a benefit of low power consumption as well as high speed signal processing in semiconductor chips formed by LSI. Enhancing the modulus of the low-k film is desirable from the standpoint of maintaining mechanical reliability, which is directly related to the electrical function, in the packaging process of semiconductor products. In order to keep packaging reliability, the modulus should be kept higher than 5 GPa, and preferably higher than 6 GPa.

The porous low-k insulating film with high modulus is preferably formed by adding a UV cure process to the porous film. The film is preferably formed from only cyclic siloxane precursors. The pore structure is formed from the ring-type siloxane, which is the main frame of the precursor monomer. These cyclic moieties are interconnected by decomposing of their side-chains, which is enhanced by UV cure selectively while avoiding breakage of the Si—O bonds within the ring structures.

The low-k insulating film according to the present invention preferably possesses the following physical characteristics:

carbon content (XPS): higher than 30%, preferably in the range of 35-60%;

porosity (EP): less than 20%, preferably 5-15%;

pore size distribution: more than 80% of pores are less than 1 nm in diameter;

bonding structure: contains —Si—O—, —Si—CH₂—Si—, and —Si—CₓH₂ₓ₊₁ linkages in the film.

Such films have been found to provide superior performance from the standpoint of process-induced damage (PID), time-dependent dielectric breakdown (TDDB) reliability of the integrated Cu interconnect, and high modulus to achieve high packaging reliability.

The ring structure of the cyclic siloxane precursors is the origin of the pores in the resultant film. Since the pores are a closed structure, the film does not offer significant pathways for particles to come into the film, which is an advantage for high PID immunity. The molecular weight of the precursors should be relatively low, to facilitate their delivery to a CVD chamber in a liquid state. Preferred are alkylated cyclic siloxanes in which the number of Si—O pairs is two, three, and four. Mixtures of such alkylated cyclic siloxanes can be used, but the precursor layer is preferably free of other precursors such as hydrocarbons and non-cyclic siloxanes. Even if one precursor molecule is a solid, it can be dissolved in another material to make a liquid mixture.

Each silicon atom within the cyclic siloxane ring structure has attached thereto two hydrocarbon side-chains. Two different types of side-chains are included in one molecule, namely an unsaturated hydrocarbon group and an alkyl group. Each silicon can have both groups or can have a pair of either group, however, there should be both groups in one molecule. Unsaturated hydrocarbon contributes to polymerization to connect one molecule with another effectively and tightly. In order to make a tight connection, a short carbon chain is preferable. So, the most preferable structure here is vinyl, —CH═CH₂, but the invention is not limited in this respect.

The alkyl group provides steric hindrance to keep the molecules at an appropriate distance to one another, so as to produce a less dense film. This alkyl group also shelters the Si—O ring-structure geometrically from the plasma which could otherwise break the ring structure. A third role of this alkyl group is to avoid severe carbon depletion and to keep Si—C bonds in the final film.

Too high a proportion of hydrocarbon degrades the elastic modulus of the film and also fails to form cross-linking from C═C bonds because the adjacent molecules are in that case spaced too far apart. Consequently, preferred alkyl groups are methyl, ethyl, propyl, and butyl groups, including not only n-propyl and n-butyl, but also, and more preferably, i-propyl, i-butyl and t-butyl. Among these, isopropyl group is the most preferred in terms of three dimensional structures, but the invention is not limited in this respect.

In order to suppress over-decomposition of the source material in the plasma-enhance CVD process, the temperature and plasma conditions were carefully investigated. For example, the temperature is preferably in the range of 250-400° C., and RF power for plasma generation is preferably in the range of 150-400 W.

In the final step of the CVD process, ramping down of RF power and precursor flow result in deposition of raw or unactivated precursor on the top surface of the deposited film. This can lead to instability of the film, in which k-value increases with elapsed time. In-situ plasma treatment just after deposition is therefore preferred, as it has a benefit to remove such unstable surface layers.

In this plasma treatment, the introducing gas is for example, Ar, He, or Xe. In addition to these gases, reactive species such as H₂, HNO₃, O₂, and so on can be added to promote decomposition of surface instable layer. However, just after CVD including plasma surface treatment, we found that the maximum elastic modulus was 3 to 5 GPa, which is not optimum for packaging reliability.

However, we unexpectedly discovered that applying a UV cure at elevated temperatures served to enhance the bonding structure related carbons without adversely affecting the Si—O bonds within the ring structures. The UV light source is preferably a broadband including the wavelength of at least 200+/−50 nm. UV light provides energy selectively to C═C or C—C bonds without breaking the Si—O ring structure. UV energy and thermal energy break some C—C bonds but the saturated alkyl substituents protect the Si—C bonds, thereby to preserve a low-k value.

The temperature at which the UV cure is conducted is also important. Temperatures higher than 400° C. may cause excessive bond breaking, such as Si—C bonds Si—O bonds, to promote SiO₂-like cross linking, resulting in higher k-values. Therefore, the temperature during the UV cure should be in the range of 200-400° C., preferably 250-350° C.

The duration of the UV cure depends on the thickness of the precursor film and the temperature. For example, a time range of from 50-250 seconds, for example 150 seconds, is suitable for a precursor layer of 400-500 nm thickness and a cure temperature of 350-400° C. However, the time range should be from 50-150 seconds, for example 100 seconds, when the thickness of the precursor layer is 200-400 nm and the cure temperature is 300-350° C.; whereas the time range should be from 15-75 seconds, for example 45 seconds, when the thickness of the precursor layer is 100-200 nm and the cure temperature is 300-350° C. or when the thickness of the precursor layer is 50-100 nm and the cure temperature is 250-350° C.

This UV cure does not need to remove porogen, as the films of the present invention are preferably porogen-free. Porogen removal by application of UV energy requires higher temperatures and takes more time than the present re-bonding process, which can be carried out under relatively mild UV cure conditions.

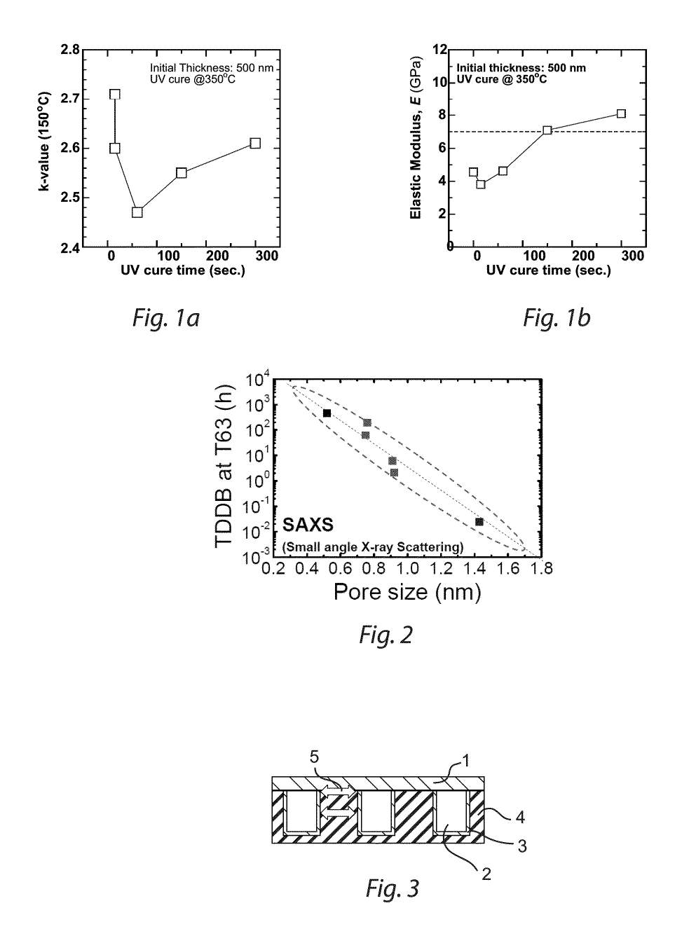

FIGS. 1a and 1b show the k-value and modulus of an exemplary film as a function of UV cure time at 350° C. The best results of 2.55 low relative permittivity (k-value) and high elastic modulus of 7.09 GPa were obtained for a cure time of 150 seconds. The precursors used to make the film tested in these figures was a mixture of three-membered Si—O ring and four membered Si—O ring. Both compounds had an isopropyl and vinyl group on each Si atom. The ratio of the 3-Si compound to the 4-Si compound was 4:3.

Preferred embodiments of the methods and devices according to the present invention are capable of providing one or more of the following advantages:

Pore size can be controlled over a tight distribution of small pore sizes, which promotes high dielectric reliability.

Carbon content can be kept relatively high, which promotes high immunity against PID.

A tight bonding structure can be formed apart from the Si—O ring structures, which promotes a high elastic modulus in the insulating film.

We found as shown in FIG. 2 that time-dependent-dielectric-breakdown (TDDB) between the copper lines in the integrated interconnect is well correlated with individual pore size of the porous low-k film which is implemented in the interconnect. As shown in FIG. 3, reference numeral 1 designates a dielectric cap, reference numeral 2 designates a copper interconnect, reference numeral 3 designates a barrier metal, and reference numeral 4 designates a low-k insulating film according to an embodiment of the present invention. The arrows 5 in FIG. 2 signify the path of capacitive crosstalk that would be present in conventional devices, and hence the dielectric reliability in devices according to preferred embodiments of the present invention.

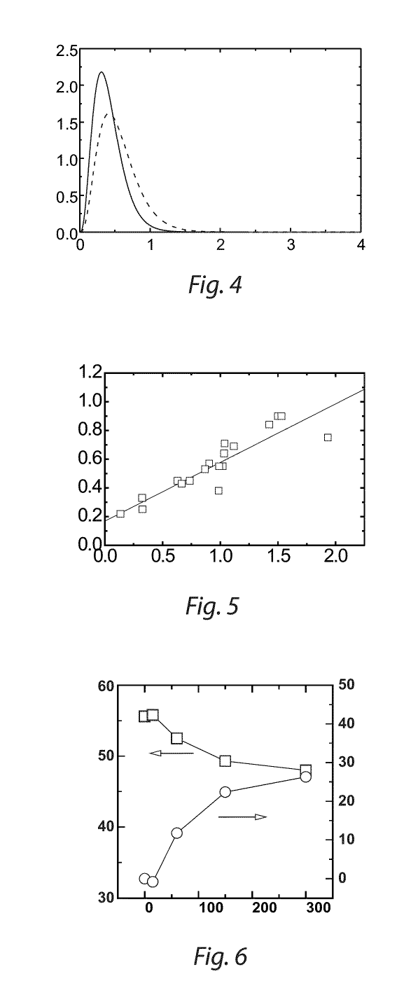

As shown in FIG. 4, the non-porogen type porous low-k can control the pore size and its distribution, where the units of the abscissa are pore diameter in nm, and the units of the ordinate are distribution in nm-1. The solid curve shows the pore distribution in low-k insulating film according to an embodiment of the present invention as deposited by CVD, whereas the broken lines shows the pore distribution after UV cure as described herein. Thus, the UV cure does not significantly deteriorate the tight particle size distribution, and both curves in FIG. 4 are significantly taller and more left-shifted (i.e., smaller pores) than curves for conventional porogen-type materials.

Since the pore size in the non-porogen type film is designed as a molecular structure, the size can be controlled to be small and distribution can be tight.

In particular, preferably more than 80% of pores are distributed in the range of less than 1 nm in the non-porogen type film by using the proposed source material.

We also found that the PID immunity is closely correlated with porosity %/carbon % ratio in the film as shown in FIG. 5. Here, PID is defined as damage layer thickness in the low-k film normalized with those in the control film, and is expressed on the ordinate of the graph of FIG. 5 in arbitrary units. The porosity %/carbon % ratio in the film is set forth on the abscissa. From this correlation, it is apparent that it would be desirable to maintain a high carbon content and a low porosity for the low-k dielectric. In order to keep desired interconnect capacitance after integration, we prefer that PID should be less than 0.4, which means that the porosity %/carbon % ratio should be less than 0.5.

In FIG. 6, the left-side ordinate (square data points) shows percentage carbon content and the right-side ordinate (round data points) shows percentage carbon reduction, in a film of initial thickness 500 nm that was UV cured at 350° C. As can be seen in that figure, the carbon amount was reduced by approximately 20% after 150 seconds of cure, which is good for k-value and modulus. However, the total carbon content in the film is still 50%, or only a 5% drop from the initial number, at this cure condition.

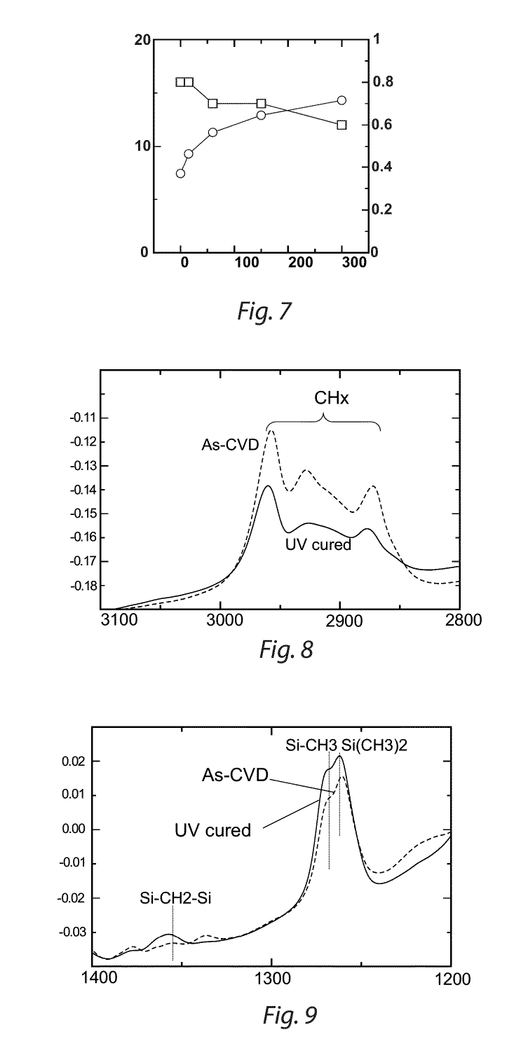

In FIG. 7, the left-side ordinate (round data points) shows percentage porosity and the right-side ordinate (square data points) shows pore size in nm (as measured by ellipsometric porosimetry (EP)), in a film of initial thickness 500 nm that was UV cured at 350° C. As can be seen in that figure, although porosity increases with UV cure time, the value was still only 13% after 150 seconds of UV curing. Consequently, the porosity/carbon ratio after 150 seconds of UV cure is 0.26, which is still well below the target maximum value of 0.5.

Bonding structures are evaluated by Fourier Transform Infrared Spectroscopy (FTIR) analysis before and after UV cure, as shown in FIG. 8, whereas FIG. 9 abstracts the behavior of featured bonding structures. In these figures, the units of the abscissa are wavenumbers in cm-1, and the units of the ordinate are arbitrary units representing absorbance. The broken lines in these figures represent the film as deposited by CVD, whereas the solid lines in these figures represent the film after UV cure.

It will thus be appreciated that the CHx peaks of the film are reduced by UV cure, indicating that hydrocarbon side-chains are decomposed during the UV cure. Si(CH₂)(CH₂)ₓ groups are also decreased, which, as discussed above, is attributed to removal of a part of the alkyl groups, and/or a decrease in the carbon number of part of the alkyl groups.

In spite of the decrease in CHx, the incidence of Si—CH₃ and Si(CH₃)₂ groups in the film increased after UV cure, further evidencing that higher carbon number alkyl groups are shortened to lower carbon number alkyl groups, and especially methyl. However, Si—C bonds are preserved, which contributes to low-k value.

Finally, the —Si—CH₂—Si— linkage was detected after UV cure. This indicates that adjacent molecules are linked with each other by abridging methylene —CH₂— structure. This bridging structure enhances mechanical strength of the film, or modulus, and correspondingly improves the packaging reliability of semiconductor devices incorporating such low-k porous insulating films.

From the various analyses described above, we can identify the reformation of bonding structures during the UV cure process. UV cure reduced the alkyl order and sometimes eliminated alkyl groups. Alkyl groups initially fill some part of the intermolecular space and keep molecules at a greater distance from one another. Reduction in alkyl order creates open space between molecules, resulting in increasing porosity and k-value reduction, as shown in FIGS. 1 and 7. However, further curing leads to increasing k-values, as shown in FIG. 1, which is attributed to a loss of Si—C bonding associated with too great a loss of alkyl groups. Even in that case, porosity still steadily increases due to more open spaces created.

UV cure also enhances another reaction for the C═C bond. In particular, UV energy breaks the C═C bond to make —Si—C— radicals, followed by cross-liking with silicon of the adjacent molecules that have lost the hydrocarbon side-chains. This bridging reaction forms strong Si—C—Si chains between molecules to make a polymer-like network with high modulus.

As discussed above, the embodiments and examples discussed herein are non-limiting, and various constitutions other than those described above can also be adopted.

It is furthermore apparent that the present invention may be variously modified without departing from the scope and spirit of the present invention as set forth in the accompanying claims.

What is claimed is:

1. A method of making a porous insulating film, comprising:
forming a precursor layer over a semiconductor substrate by depositing at least one cyclic siloxane compound having at least one hydrocarbon side chain by CVD; and
converting the precursor layer to a porous insulating film by exposing the insulating film to UV energy under conditions such that adjacent molecules of the at least one cyclic siloxane compound are bonded via a hydrocarbon group and the porous insulating film has an elastic modulus as measured by a nanoindenter of greater than 5 GPa.

2. The method according to claim 1, wherein the precursor layer is formed by plasma-enhanced CVD.

3. The method according to claim 2, wherein the at least one cyclic siloxane compound is introduced into a plasma during said forming step.

4. The method according to claim 2, wherein the at least one cyclic siloxane compound is treated with plasma in situ after formation of the precursor layer.

5. The method according to claim 1, wherein the porous insulating film has a lower carbon content than the precursor layer.

6. The method according to claim 1, wherein the porous insulating film includes Si—CH2-Si bonds.

7. The method according to claim 1, wherein silicon atoms of adjacent siloxane rings within the porous insulating film are joined by a methylene (—CH₂—) linkage.

8. The method according to claim 1, wherein the precursor layer is formed by plasma-enhanced CVD at a temperature within the range of 250-400° C.

9. The method according to claim 1, wherein the precursor layer is formed by plasma-enhanced CVD at an RF power in the range of 150-400 W.

10. The method according to claim 1, wherein the precursor layer is exposed to UV energy at a temperature of 200-400° C. for a time period less than 300 seconds.

11. The method according to claim 10, wherein the time period is from 15-150 seconds.

12. The method according to claim 10, wherein the time period is from 15-75 seconds.

13. The method according to claim 10, wherein the precursor layer is exposed to UV energy at a temperature of 250-350° C.

14. The method according to claim 1, wherein the UV energy is supplied by a broadband UV light source including a wavelength of at least 200±50 nm.

15. The method according to claim 1, wherein the precursor layer is deposited from a single liquid source.

16. The method according to claim 1, wherein the at least one cyclic siloxane compound is selected from the group consisting of compounds of the formulae: 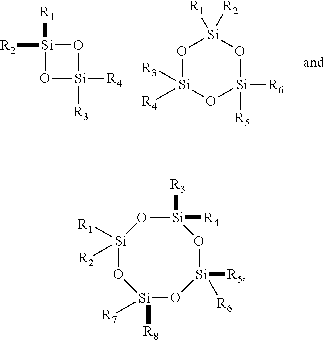
wherein R₁-R₈ are each independently selected from the group consisting of saturated C₁-C₄ alkyl and unsaturated C₂-C₄ alkylene, and wherein each of the at least one cyclic siloxane compounds comprises at least one saturated C₁-C₄ alkyl group and at least one unsaturated C₂-C₄ alkylene group.

17. The method according to claim 1, wherein the at least one cyclic siloxane compound is selected from the group consisting of compounds of the formulae: 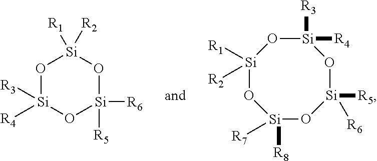
wherein R₁, R₃, R₅ and R₇ are each saturated C₁-C₄ alkyl and wherein R₂, R₄, R₆ and R₈ are each unsaturated C₂-C₄ alkylene.

18. The method according to claim 17, wherein R₁, R₃, R₅ and R₇ are each methyl, ethyl or isopropyl and wherein R₂, R₄, R₆ and R₈ are each vinyl.

19. The method according to claim 16, wherein the at least one cyclic siloxane compound comprises a mixture of compounds of the formulae:

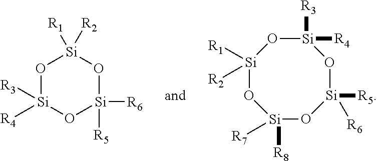

20. The method according to claim 19, wherein the mixture comprises compounds of the formula 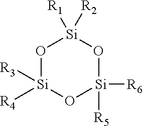
in a molar ratio of about 4:3 to compounds of the formula

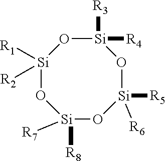

21. A semiconductor device comprising a semiconductor substrate and a porous insulating film overlying said semiconductor substrate, wherein said porous insulating film is a low-k SiOCH film having cyclic siloxane moieties interconnected by hydrocarbon linkages, said porous insulating film having a carbon content of greater than 30 at % as measured by X-ray photoelectron spectroscopy, a porosity of less than 20% as measured by ellipsometric porosimetry, a pore size distribution wherein greater than 80% of pores have a diameter of less than 1 nm, an elastic modulus as measured by a nanoindenter of greater than 5 GPa, said porous insulating film further comprising linkages including —Si—O—, —Si—CH₂—Si—, and —Si—CₓH₂ₓ₊₁, wherein x is an integer from 1 to 4.

22. The semiconductor device according to claim 21, wherein said porous insulating film is an interlayer insulating film comprising damascene copper interconnects formed in trenches and vias in said interlayer insulating film.

23. The semiconductor device according to claim 21, wherein said carbon content is in the range of 40-60 at %.

24. The semiconductor device according to claim 21, wherein said porosity is in the range of 5-15%.

25. The semiconductor device according to claim 21, wherein said porous insulating film has a relative permittivity of less than 2.7.

26. The semiconductor device according to claim 21, wherein said porous insulating film has a relative permittivity of less than 2.6.

27. The semiconductor device according to claim 21, wherein said porous insulating film has an elastic modulus as measured by a nanoindenter of greater than 6 GPa.

28. The semiconductor device according to claim 21, wherein said porous insulating film has an elastic modulus as measured by a nanoindenter of greater than 7 GPa.

29. The semiconductor device according to claim 21, wherein said porous insulating film is deposited from a single liquid source.

30. The semiconductor device according to claim 21, wherein said porous insulating film is formed by polymerizing molecules comprising at least one cyclic siloxane compound selected from the group consisting of compounds of the formulae: 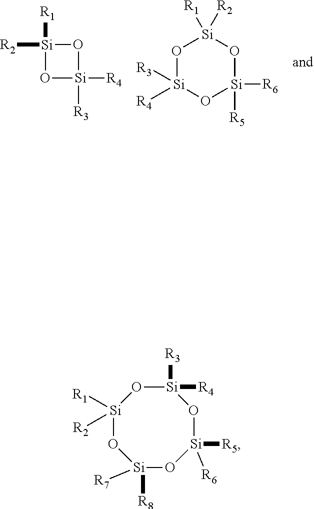
wherein R₁-R₈ are each independently selected from the group consisting of saturated C₁-C₄ alkyl and unsaturated C₂-C₄ alkylene, and wherein each of said at least one cyclic siloxane compounds comprises at least one saturated C₁-C₄ alkyl group and at least one unsaturated C₂-C₄ alkylene group.

31. The semiconductor device according to claim 21, wherein said porous insulating film is formed by polymerizing molecules comprising at least one cyclic siloxane compound selected from the group consisting of compounds of the formulae: 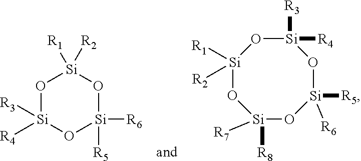
wherein R₁, R₃, R₅ and R₇ are each saturated C₁-C₄ alkyl and wherein R₂, R₄, R₆ and R₈ are each unsaturated C₂-C₄ alkylene.

32. The semiconductor device according to claim 31, wherein R₁, R₃, R₅ and R₇ are each methyl, ethyl or isopropyl and wherein R₂, R₄, R₆ and R₈ are each vinyl.
